(19) United States
(12) Patent Application Publication
(10) Pub. No.: US 2026/0168962 A1
(43) Pub. Date: Jun. 18, 2026

(54) APPARATUS AND METHODS FOR DETECTING IMPURITIES IN SEMICONDUCTOR PROCESSING TOOLS

(71) Applicant: TAIWAN SEMICONDUCTOR MANUFACTURING COMPANY, LTD., Hsinchu (TW)

(72) Inventors: Ming Da YANG, Taichung (TW); Chun-Hsuan LIN, Hsinchu (TW); Kuo-Lun TUNG, Hsinchu (TW); Yi-Chen LI, Taichung (TW)

(21) Appl. No.: 19/171,225

(22) Filed: Apr. 5, 2025

Related U.S. Application Data
(60) Provisional application No. 63/734,094, filed on Dec. 14, 2024.

(51) Int. Cl. G01N 27/90; G01D 5/20; G01D 5/243

(52) U.S. Cl. CPC G01N 27/9006; G01D 5/2006; G01D 5/243; G01N 27/9046

(57) ABSTRACT

Embodiments of the present disclosure relate to apparatus and methods for detecting impurities in semiconductor processing tools in real time. The real time electromagnetic impedance and resonance frequency behavior detection/analysis can provide specific ion/particle/chemical information and/or fingerprint in the semiconductor process.

### CROSS-REFERENCE TO RELATED APPLICATIONS

This application claims priority to the U.S. Provisional Patent Application Ser. No. 63/734,094 filed Dec. 14, 2024, which is incorporated by reference in its entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

Process sensitivities also increase with scaling down. Therefore, there is a need for improved impurity detection.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A, 1B, 1C, and 1D schematically illustrate an impurity monitoring apparatus according to embodiments of the present disclosure for detecting impurities in semiconductor processing tools.

FIGS. 2A, 2B, 2C, and 2D schematically illustrate a method for detecting impurities using the impurity monitoring apparatus according to embodiments of the present disclosure.

FIGS. 3A-3G schematically illustrate various applications using the impurity monitoring apparatus according to embodiments of the present disclosure.

FIGS. 4A-4B schematically illustrate impurity monitoring apparatus according to some embodiments of the present disclosure.

FIGS. 5A-5M schematically illustrate various magnet and coil arrangements according to embodiments of the present disclosure.

FIGS. 6A-6C schematically illustrate an impurity monitoring apparatus according to embodiments of the present disclosure.

FIGS. 7A-7D schematically illustrate flat coil designs according to embodiments of the present disclosure.

FIGS. 8A-8B schematically illustrate magnet and coil arrangements according to embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “top,” “upper” and the like, may be used herein for ease of description to describe one element or feature's relationship to another element(s) or feature(s) as illustrated in the figures. The spatially relative terms are intended to encompass different orientations of the semiconductor device in use or operation in addition to the orientation depicted in the figures. The apparatus may be otherwise oriented (rotated 90 degrees or at other orientations) and the spatially relative descriptors used herein may likewise be interpreted accordingly.

Embodiments of the present disclosure relate to apparatus and methods for detecting impurities in semiconductor processing tools in real time. Particularly, embodiments of the present disclosure provide an impurity monitoring apparatus having a detection module and an analyzing module. The detection module comprises a housing defining a testing volume, a magnet and a coil assembly disposed around the testing volume. The testing volume is configured to receive a target, such as a filter or a section of supply tubing of a semiconductor processing tool. The impurity monitoring apparatus may be used in real time when the semiconductor processing tool is operating. The detection module captures electromagnetic properties related to re-emission of radio waves of impurities, such as specific ions, particles, chemicals, or the like, in the target filter or tubing. The analyzing module identifies electromagnetic impedance and resonance frequency behaviors of the captured electromagnetic properties. The real time electromagnetic impedance and resonance frequency behavior detection/analysis can provide specific ion/particle/chemical information and/or fingerprint in the semiconductor process. Particularly, the impurity monitoring apparatus according to the present disclosure can provide real time impurity (ion/chemical/particle) detection to ppb (part per billion) level in real time.

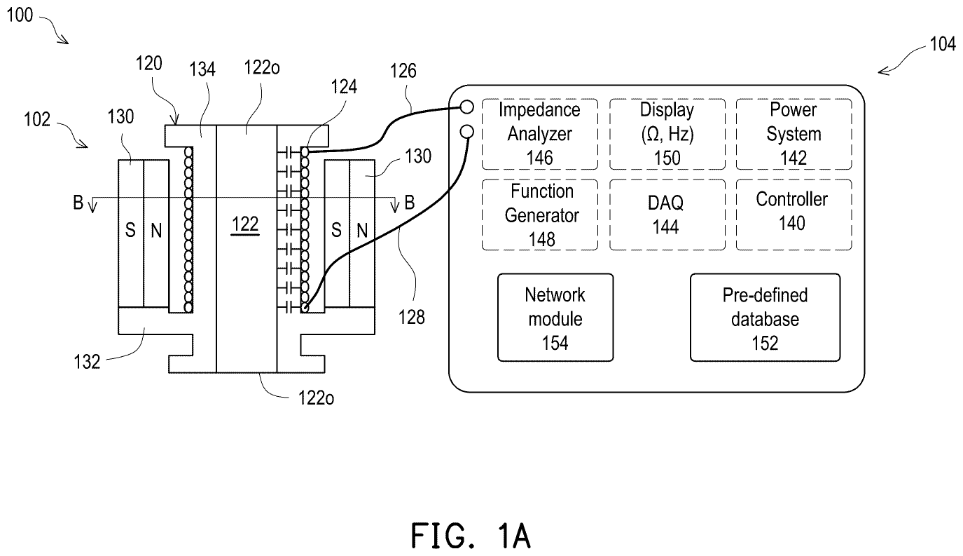

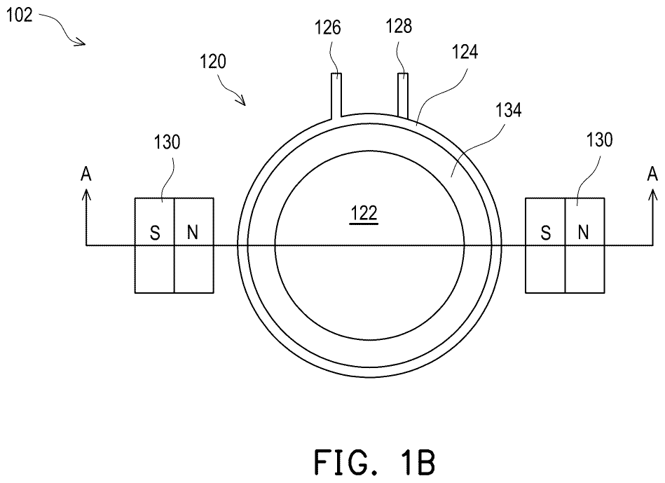

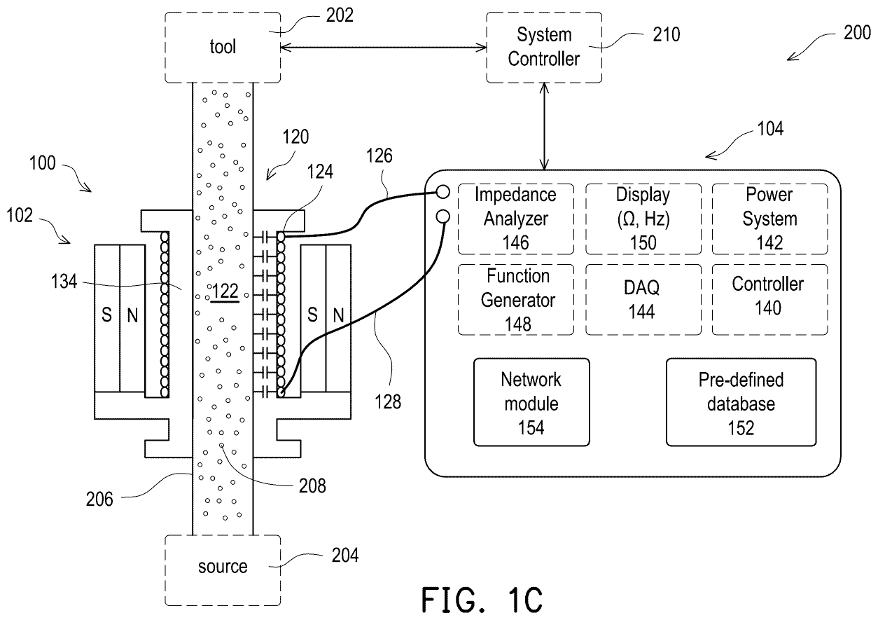

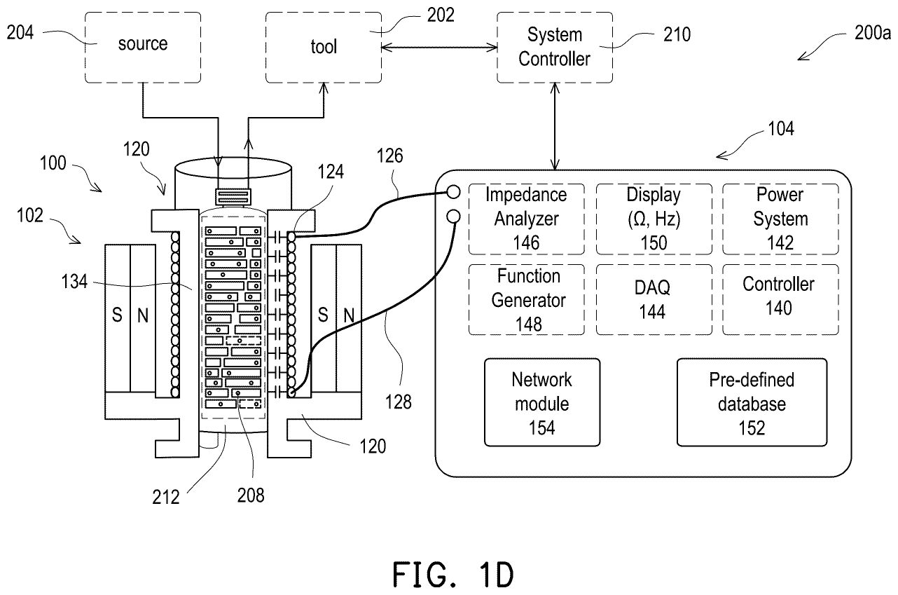

FIGS. 1A, 1B, 1C, and 1D schematically illustrate an impurity monitoring apparatus 100 according to embodiments of the present disclosure. The impurity monitoring apparatus 100 may detect and measure impurities in semiconductor processing tools in real time.

As shown in FIG. 1A, the impurity monitoring apparatus 100 includes a detection module 102 and an analyzing module 104. The detection module 102 is configured to dispose around a testing target, such as a filter or a section of fluid supply tube. The detection module 102 measures electromagnetic re-emissions from the testing target and transmits the measurement to the analyzing module 104. The analyzing module 104 is configured to process the measurements to obtain specific impurity information, such as specific ion/particle/chemical information in the testing target.

In FIG. 1A, the detection module 102 is shown in a side cross sectional view. FIG. 1B is a top cross sectional view of the detection module 102. As shown in FIGS. 1A and 1B, the detection module 102 includes a housing 120, a coil assembly 124, and a magnet assembly 130.

The coil assembly 124 is disposed on the housing 120 so that the housing 120 and the coil assembly 124 define a testing volume 122. The testing volume 122 is configured to receive a testing target therein. In some embodiments, the testing volume 122 has a shape of a cylindrical column. The testing volume 122 may include one or more openings 1220 to allow passage of the testing target. In some embodiments, the testing volume 122 is a through hole to allow passage of a fluid supply tube there through. Alternatively, the testing volume 122 may be a cylinder with a dead end to receive a filter unit therein.

The housing 120 provides structural definitions so that the coil assembly 124 substantially surrounds the testing volume 122. In some embodiments, the housing 120 includes a sidewall portion 134 defining the testing volume 122. In some embodiments, the sidewall portion 134 is one continuous sidewall disposed between the testing volume 122 and the coil assembly 124. In other embodiments, the sidewall portion 134 may include two or more sections removably connected together. In some embodiments, the sidewall portion 134 may include other designs, such as bars, mesh, or the like. At least a portion of the housing 120 is made of materials transparent to radio frequency (RF) waves so that the coil assembly 124 may apply RF waves to and receive RF remissions from the testing target in the testing volume 122. In some embodiments, the housing 120 is made of polypropylene, nylon, polycarbonate, PVC, ceramic composite, MXene-based materials, or other RF wave transparent material.

The coil assembly 124 may include one or more wired coils disposed around the testing volume 122. In some embodiments, the coil assembly 124 may include one or more helical coil to generate a solenoid during operation. The coil assembly 124 is configured to generate an electromagnetic field in the testing volume 122 when a RF pulse is applied. In some embodiments, the coil assembly 124 is also configured to capture RF re-emissions from impurities in the testing target disposed in the testing volume 122. The coil assembly 124 may be connected to the analyzing module 104 via terminals 126, 128. In some embodiments, as shown in FIGS. 1A, 1B, the coil assembly 124 may include a spiral coil wound about the testing volume 122. As discussed below, the coil assembly 124 may include two or more wired coils and/or coils of other arrangements to achieve desired function.

The magnet assembly 130 is configured apply a base magnetic field in the testing volume 122. Unlike the electromagnetic field generated by the coil assembly 124, which is pulsed, the base magnetic field 130mf may remains active or present during operation of the impurity monitoring apparatus 100. In the embodiments of FIGS. 1A and 1B, the magnetic assembly 130 includes a pair of permanent magnets. Alternatively, the magnetic assembly 130 may include wired coils positioned to generate an electromagnetic field in the testing volume 122. In some embodiments, the magnet assembly 130 may include two or more sets of magnets.

The magnet assembly 130 and the coil assembly 124 are arranged so that the magnetic field of the magnet assembly 130 and the magnetic field from the coil assembly 124 are at different directions. In some embodiments, the magnet assembly 130 is attached to the housing 120. In some embodiments, the magnet assembly 130 is fixedly attached to the housing 120. For example, the housing 120 may include a flange portion 132 extending from the sidewall portion 134. The flange portion 132 provides structural support to the magnet assembly 130.

In some embodiments, the magnetic field of the magnet assembly 130 and the magnetic field from the coil assembly 124 are perpendicular to each other. In other embodiments, the magnetic field of the magnet assembly 130 and the magnetic field from the coil assembly 124 form an angle.

The analyzing module 104 is configured detect and monitor impurities in a testing target disposed in the testing volume 122 of the detection module 102. Depending on the design of the impurity monitoring apparatus 100, the analyzing module 104 may include a combination of various function blocks.

The analyzing module 104 may include a controller. The controller 140 may be a computing device that includes a microprocessor, memory and input/output circuitry, e.g., a programmable computer. The controller 140 may include or is in operable communication with a memory having stored thereon a plurality of instructions that when executed to perform various measurement and analyzing operations. The controller 140 may communicate with other function blocks in the analyzing module 104.

The analyzing module 104 may include a power system 142. The power system 142 is configured to supply power to the detection module 102 and the equipment in the analyzing module 104. In some embodiments, when the magnet assembly 130 includes wired coils, the power system 142 may further provide AC power source to the magnet assembly 130 to generate the base magnetic field.

In some embodiments, the analyzing module 104 includes a DAQ (data acquisition) unit 144. The DAQ unit 144 is configured to sample signals from the detection module 102 via the terminals 126, 128. In some embodiments, the DAQ unit 144 may convert the measurement into a digital form for further processing, for example through the impedance analyzer 146. In other embodiments, the DAQ unit 144 may process and output the measurement in analogue form.

In some embodiments, the analyzing module 104 includes an impedance analyzer 146. The impedance analyzer 146 is configured to measure electrical impedance as a function of test frequency. For example, the impedance analyzer 146 may processed measurement from the DAQ unit 144 and abstract impedance values at various frequencies.

In some embodiments, the analyzing module 104 includes a function generator 148. The function generator 148 may be used generate RF pulses and supplies the coil assembly 124 during measurement.

In some embodiments, the analyzing module 104 may further include a display 150. The display 150 may be a monitor screen and/or indicators to provide test results and/or warning signals from monitoring function to operators. In some embodiments, the display 150 may include an LCD monitor screen or display connected to the computing device on which the controller 140 is run. In some embodiments, the display 150 may include one or more light indicators, such as light emitting diodes.

In some embodiments, the analyzing module 104 may include a network module 154. The network module 154 may be used to provide wired or wireless communications between various functional blocks in the analyzing module 104 and with the detection module 102.

In some embodiments, the analyzing module 104 further includes a pre-defined database 152. The pre-defined database 152 may include empirical data of impurities to be measured. For example, the pre-defined database 152 may include maximum resonance frequencies of a baseline processing gas and different impurities in a process tool, correlation between concentrations and measured resonance frequencies of one or more impurities being monitored, a capacitance table of a target filter at different stages of use, correlations between concentration gradients and impedances of one or more impurities being monitored, a correlation between frequencies of maximum impedance and capacitive reactance and the stage of a target filter being used, and a correlation between frequencies of maximum inductive reactance and the stage of a target filter being used, or other data and lookup tables advancing real time measurements by reducing real time data processing. In some embodiments, the pre-defined database 152 may be stored in a memory device in the computing device on which the controller 140 is run.

In some embodiments, the pre-defined database 152 may be updated continuously. For example, the controller 140 may include a deep learning artificial intelligence algorithm to refine and optimize the pre-defined database 152 using operation.

The impurity monitoring apparatus 100 may be used for real time process monitoring. FIG. 1C schematically demonstrates a system 200 including the impurity monitoring apparatus 100. The system 200 may include a process tool 202, a process chemical source 204, and a supply tubing 206 connected between the process chemical source 204 and the process tool 202. A portion of the supply tubing 206 passes through the testing volume 122 of the impurity monitoring apparatus 100 so that impurities flowing from the process chemical source 204 to the process tool 202 may be detected and monitored during operation of the system 200.

The process tool 202 may be any suitable semiconductor process tool. For example, the process tool 202 may be etch process apparatus, lithography process apparatus, such as EUV (extreme ultraviolet) lithography tool, chemical mechanical polishing (CMP) process apparatus, chemical vapor deposition (CVD) process apparatus, physical vapor deposition (PVD) process apparatus, atomic layer deposition (ALD) process apparatus, electrochemical plating (ECP) process apparatus, ion implantation process apparatus, thermal treatment apparatus, diffusion process apparatus, waste-water process apparatus, waste chemical process apparatus, and the like.

The process tool 202 may be used process various substrates, for example substrate made of silicon (Si), germanium (Ge), glass, sapphire, printed wire board, polymer material, gallium nitride (GaN), silicon carbide (SiC), and quasicrystal material, or the like.

The process tool 202 may be used to fabricate substrates comprising circuit elements, semiconductor devices, interconnection structure, backside interconnection structure, back end of line (BEOL) devices.

The process tool 202 may be connected to one or more process chemical source 204. The process chemical source 204 is configured to provide process fluid to the process tool 202 via the supply tubing 206. Even though a linear tubing is shown in FIG. 1C, the supply tubing 206 may include multiple lines, joints, control valves, flow restrictors, mass flow valves, or other devices. The process chemical supplied from the process chemical source 204 to the process tool 202 may be in the form of liquid, gas, suspension solution, a mixture of gas, liquid and solid particles. In some embodiments, the process chemical flown in the supply tubing 206 may be facility/industry material, such as deionized (DI) water, lithography photoresist, lithography developers, lithography solvent, chemical mechanical polishing slurry, acid/alkaline liquid/gas/mixture, slurry/mud, polymer fluid, organic compound fluid, processing gas, plasma containing gases, or the like.

As shown in FIG. 1C, the detection module 102 of the impurity monitoring apparatus 100 is disposed on a portion of the supply tubing 206. The portion of the supply tubing 206 is positioned within the testing volume 122 and is surrounded by the coil assembly 124. In some embodiments, the supply tubing 206 may be inserted into the through hole defined by the housing 120 of the detection module 102. In other embodiments, the housing 120 may include two or more sections and may be assembled around the supply tubing 206.

As shown in FIG. 1C, impurities 208 of interest, which may be ions, particles, chemicals, may be detected and monitored by the impurity monitoring apparatus 100 as the impurities 208 of interest flowing through the test volume of the impurity monitoring apparatus 100.

In some embodiments, the system 200 includes a system controller 210. The system controller 210 may be connected to the impurity monitoring apparatus 100, for example, connected to the controller 140 of the impurity monitoring apparatus 100. During operation, the system controller 210 may send commands to the impurity monitoring apparatus 100 to detect or monitor impurities 208 of interest particular to the process tool 202 and the process being run. The impurity monitoring apparatus 100 may detect and monitor one or more impurities 208 of interest.

In some embodiments, the system controller 210 may send commands to the impurity monitoring apparatus 100 to start a monitoring/detection operation. In some embodiments, the system controller 210 may provide impurity information, such as the specific ions/particles/chemicals, criteria, etc, for detection and monitoring operation according to the processing being performed in the process tool 202.

The impurity monitoring apparatus 100 may return detection/monitoring results to the system controller 210. For example, the impurity monitoring apparatus 100 may send warning signals to the system controller 210 when impurities being monitored reach a critical value. The system controller 210 may in turn start, adjust or stop process operation in the process tool 202.

The system 200 is capable of detecting/monitoring specific ions/particles/chemicals detection according to electromagnetic impedance and resonance frequency behavior of the specific ions/particles/chemicals. The real time electromagnetic impedance and resonance frequency behavior detection/analysis can provide specific ion/particle/chemical information and/or fingerprints in the semiconductor/industry process. The impurity monitoring apparatus 100 may enable early alarm at accuracy at single digit ppb or lower level.

FIG. 1D schematically demonstrates a system 200a including the impurity monitoring apparatus 100. The system 200a is similar to the system 200 in FIG. 1C except that the impurity monitoring apparatus 100 is disposed around a filter 212 disposed between the process tool 202 and the process chemical source 204. At least of a portion of the filter 212 is inserted in the testing volume 122 of the impurity monitoring apparatus 100 so that the impurity monitoring apparatus 100 can monitor stage of use of the filter 212. For example, at least a filter cartridge of the filter 212 is surrounded by the detection module 102 of the impurity monitoring apparatus 100. The impurity monitoring apparatus 100 may detect and measure particular species in the filter cartridge to enable determination of filter usage. In some embodiments, the filter may contain reactant liquids, such as DI water, photoresist or other chemical solutions, or reactant gases.

In some embodiments, the system controller 210 may provide information of the filter 212 to be monitor to the impurity monitoring apparatus 100. For example, the system controller 210 may provide information of the specific ions/particles/chemicals, criteria, etc, associated with the filter cartridge. Alternatively, the information of the specific ions/particles/chemicals, criteria, etc, associated with the filter cartridge may be obtained by scanning IDs of the filter cartridge and looking up a filter table stored in the pre-defined database of the impurity monitoring apparatus 100. In some embodiments, the criteria may include a range of accepted values.

The impurity monitoring apparatus 100 measures the specific ions/particles/chemicals in the filter 212. The impurity monitoring apparatus 100 may sound an alarm or return detection/monitoring results to the system controller 210 when the specific ions/particles/chemicals in the filter 212 reach a critical value. Operators may change the filter cartridge of the filter 212 upon receiving the warning, thus, preventing overuse or underuse of the filter cartridge.

In some embodiments, the impurity monitoring apparatus 100 may be disposed around an exhaust pipe of a process tool 202 to prevent harmful species from entering the environment via the exhaust.

In some embodiments, the systems 200, 200a may be combined. For example, both the supply tubing 206 and the filter 212 may be monitored by the impurity monitoring apparatus 100. In some embodiments, the system 200, 200a may include two or more impurity monitoring apparatus 100 or at least two or more detection modules 102 may be included in the systems 200, 200a so that multiple locations in the system 200, 200a may be monitored.

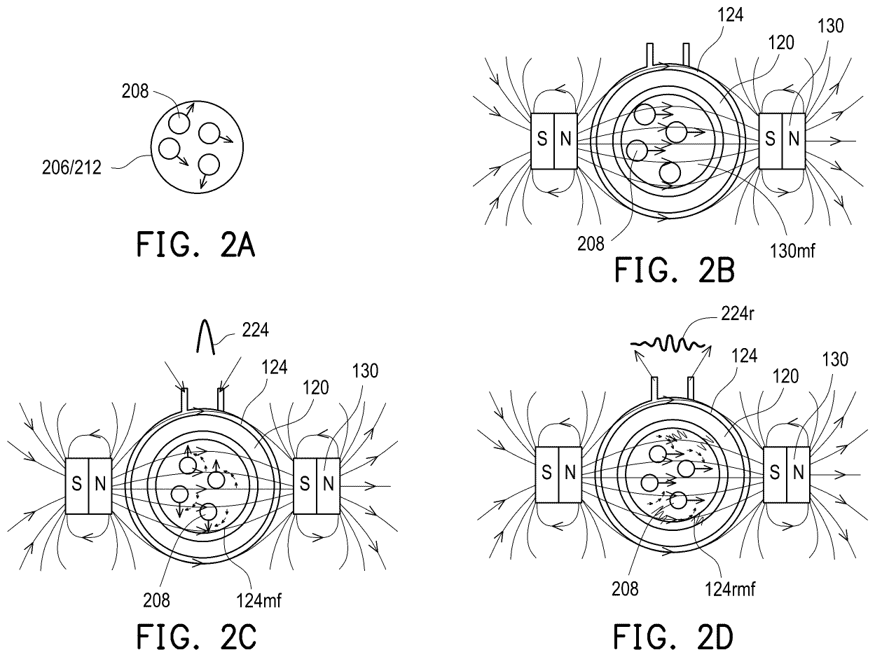

In some embodiments, impurities in a testing target may be detected and measured using a method according to the present disclosure. In some embodiments, the method includes disposing the testing target in a testing volume of the impurity monitoring apparatus 100; applying a base magnetic field to the testing target; applying a pulsed radio frequency wave to the testing target while maintaining the base magnetic field; and detecting an impedance of the testing target when the radio frequency pulse ends while maintaining the base magnetic field. In some embodiment, detecting impedance of the testing target comprises detecting at least one of resistance, inductive reactance, and capacitive reactance of the testing target. FIGS. 2A, 2B, 2C, and 2D schematically illustrate the method for detecting impurities in a testing target using the impurity monitoring apparatus 100 according to embodiments of the present disclosure.

FIG. 2A schematically illustrates impurities in a test target. FIG. 2A is a schematic cross section of a testing target. The testing target may be the supply tubing 206 or the filter 212 in the systems 200, 200a. FIG. 2A schematically illustrates magnetic moments of protons of impurities 208 in the natural state. Particularly, in the natural state, magnetic moments of protons of impurities 208 are randomly oriented.

FIG. 2B schematically illustrates impurities in the testing target when a base magnetic field is applied. FIG. 2B is a schematic cross section of the testing target when the testing target is inserted in the testing volume 122 of the detection module 102 of the impurity monitoring apparatus 100. The magnet assembly 130 imposes a base magnetic field 130mf to the testing volume 122. In the embodiment of FIG. 2B, the magnetic assembly 130 includes a pair of permanent magnets disposed across the testing volume 122 along the same orientation, resulting the base magnetic field 130mf as a linear magnetic field across the testing volume 122. As shown FIG. 2B, orientations of magnetic moments of protons of impurities 208 change under the base magnetic field 130mf. The orientations of magnetic moments of protons of impurities 208 become aligned with the base magnetic field 130mf.

FIG. 2C schematically illustrate the impurities in the testing target when a RF wave is applied to excite the impurities. FIG. 2C is a schematic cross section of the testing target when a pulsed RF wave 224 is applied. In some embodiments, the pulsed RF wave 224 is applied to the coil assembly 124 of the detection module 102. The coil assembly 124 surrounds the testing volume 122. When the pulsed RF wave 224 is applied to the coil assembly 124, an electromagnetic field 124mf is generated in the testing volume 122. In some embodiments, the pulsed RF wave 224 is applied to the coil assembly 124 via the terminals 126, 128. As discussed above, the coil assembly 124 and the magnet assembly 130 are arranged to have magnetic fields along different directions. In the arrangement of FIG. 2C, the electromagnetic field 124mf is perpendicular to the base magnetic field 130mf in the testing volume 122. When the electromagnetic field 124mf is generated by the pulsed RF wave 224 in the testing volume 122, the orientation of the magnetic movements of portions of impurities 208 moves towards the direction of the electromagnetic field 124mf. As shown in FIG. 2C, orientations of the protons of impurities 208 are no longer aligned with the base magnetic field 130mf. In some embodiments, inductance, capacitance, and/or resistance may be detected by sampling signals between the terminals of the coil assembly 124.

The frequency of the pulsed RF wave 224 may be selected according to the impurities of interest. In some embodiments, the RF wave 224 has a frequency in a range between about 1 k Hertz and about 10 M Hertz. The pulse of the pulsed RF wave 224 may be in a range between about 1 milliseconds and about 5 milliseconds.

FIG. 2D schematically illustrate the impurities in the testing target after the pulsed RF wave 224 is ended. FIG. 2D is a schematic cross section of the testing target after pulsed RF wave 224 ends. When the pulsed RF wave 224 ends, the electromagnetic field 124mf also ends in the testing volume 122. The orientation of the magnetic movements of protons of impurities 208 flips back towards the direction aligning with the base magnetic field 130mf. The movement generates a reactive electromagnetic field 124rmf. The reactive electromagnetic field 124rmf generates a responsive electrical signal 224r in the coil assembly 124. The responsive electrical signal 224r may be captured by sampling inductance and capacitance between the terminals 126, 128 of the coil assembly 124, as shown in FIG. 2D.

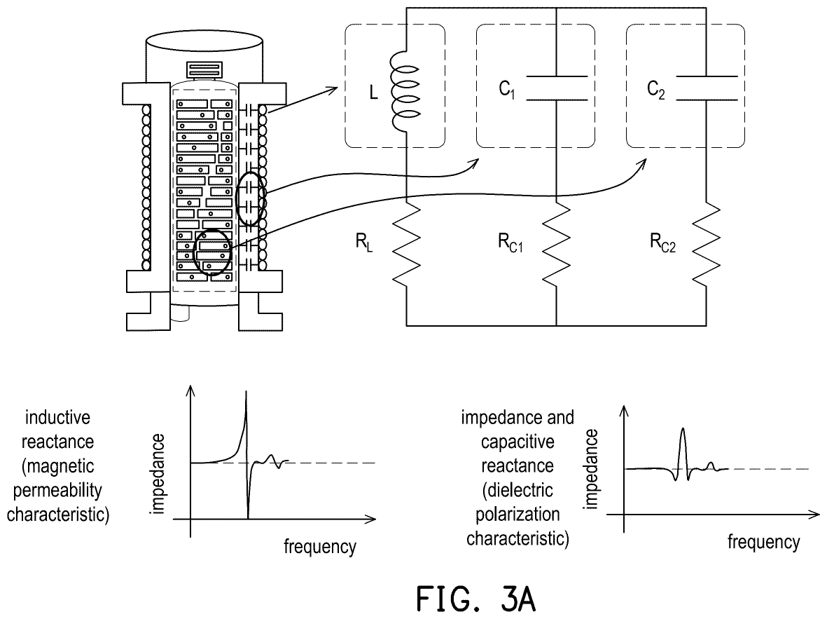

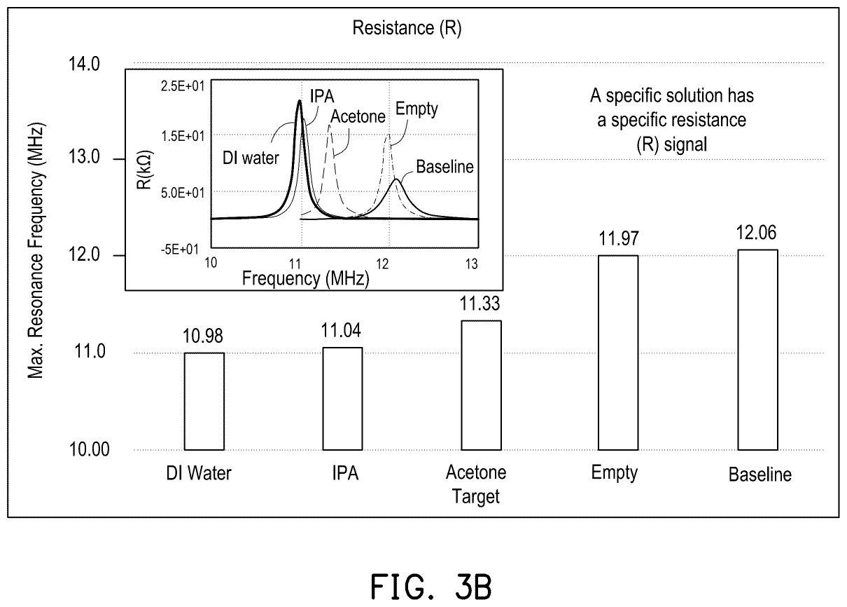

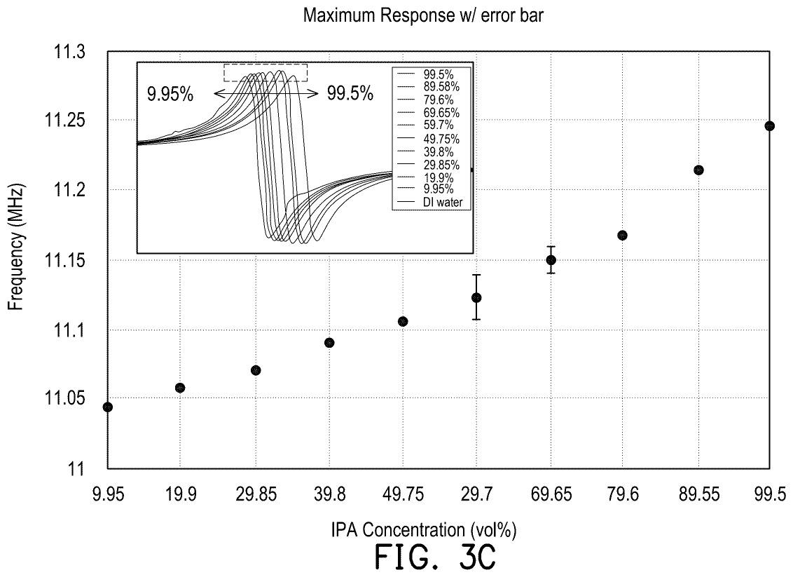

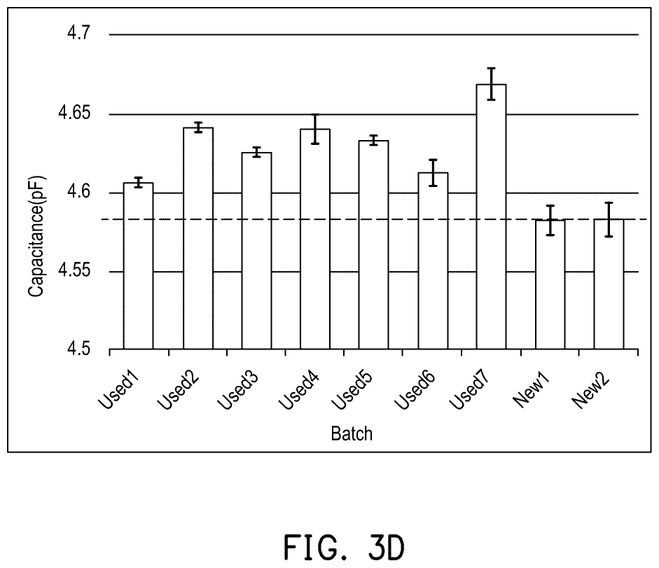

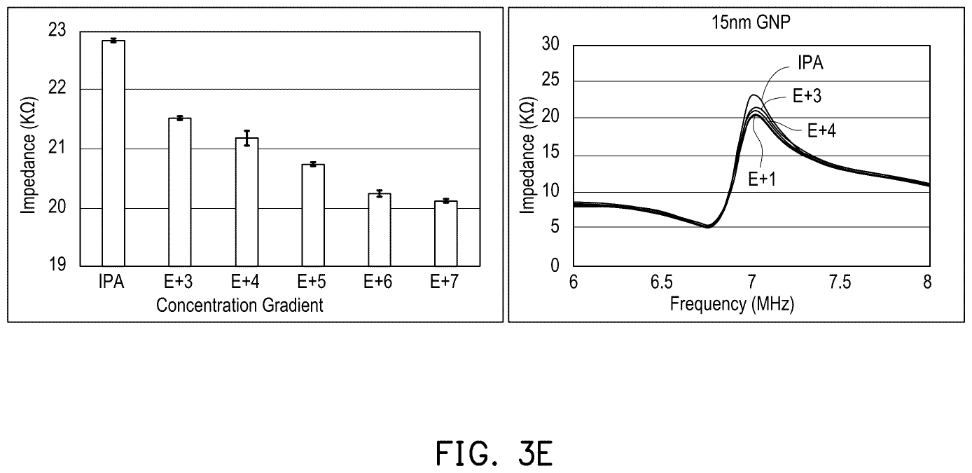

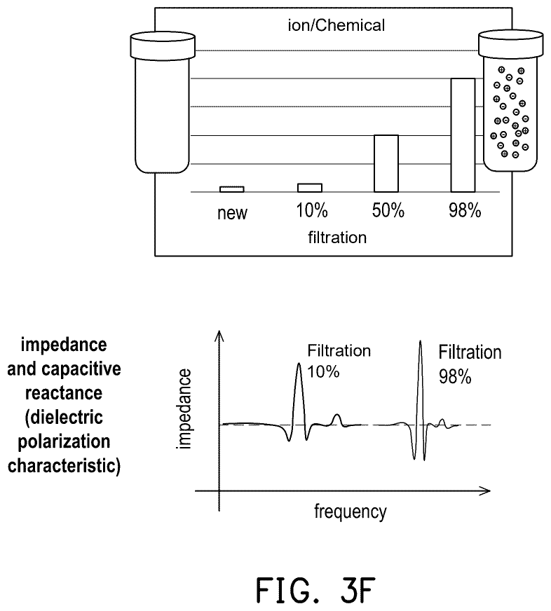

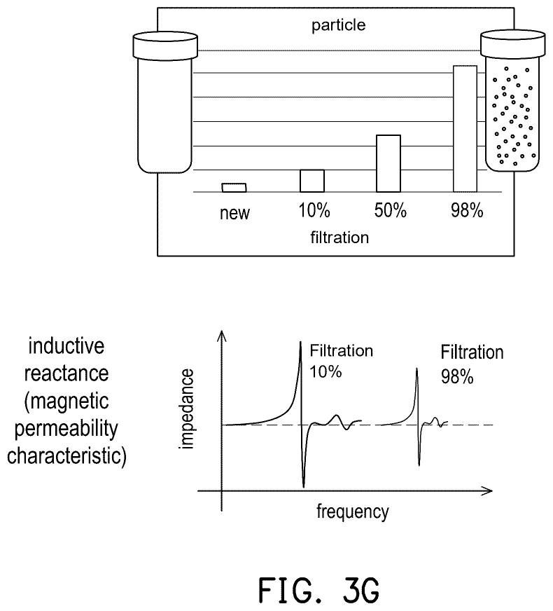

The sampled signal between the terminals 126, 128 may be analyzed to capture electromagnetic impedance and resonance frequency behavior to detect and measure the impurities of interest. FIGS. 3A-3E schematically illustrate various applications using the impurity monitoring apparatus according to embodiments of the present disclosure.

FIG. 3A is an equivalent circuit of the detection module 102, which includes a coil encircled tubing comprising fluid and different material inside. As shown in FIG. 3A, circuit elements of the detection module 102 with a testing target may include inductance L and resistance R_{L} of the coil assembly 124, capacitance C₁ and resistance R_{C1} of the medium, i.e. the housing 120, between the coil assembly 124 and the testing target, and capacitance C₂ and resistance R_{C2} of the impurities 208 in the testing target, connected in parallel. FIG. 3A further includes example impedance charts for impurities with magnetic permeability characteristics, wherein inductive reactance may be measured and analyzed, and for impurities with dielectric polarization characteristics, wherein impedance and capacitive reactance may be measured and analyzed.

Specific impurities may be detected according to impedance response or capacitance response in the frequency domain. The self-resonant frequency f is a function of inductance L and capacitance C,

$$f = \frac{1}{2 π \sqrt{LC}}$$

wherein the capacitance C is a function of relative permittivity and capacitor dimension:

$$C = {ε}_{r} {ε}_{0} \frac{A}{D}$$

where εᵣ is relative permittivity; ε₀ is electric constant, C is capacitance, A is area of overlapping plates; d is separation between the plates, wherein the inductance L may be calculated:

$$L = \frac{{μ}_{0} {N}^{2} A}{l}$$

where μ₀ is the permeability of free space, N is number of turns, A is cross section area, l is coil length. Impurities may be detected by analyze measured impedance response in the frequency domain.

FIG. 3B is a schematic chart showing using the impurity monitoring apparatus 100 to identify a specific solution in a supply tubing disposed through the testing volume 122 of the impurity monitoring apparatus 100. As shown in FIG. 3B, when detected resistance-frequency signals have different characteristics (1) when no testing target is present (baseline), (2) when an empty testing target is present (empty), (3) when acetone is present in the testing target, (4) when IPA is present in the testing target, and (5) when DI water is present. Therefore, a specific solution has a specific resistance signal. By identifying the maximum resonance frequency from the resistance-frequency signal, it is possible to identify the particular solution in the testing solution using the impurity monitoring apparatus according to the present disclosure.

FIG. 3C is a schematic chart showing using the impurity monitoring apparatus 100 to determine concentration of a chemical in a supply tubing disposed through the testing volume 122 of the impurity monitoring apparatus 100. As shown in FIG. 3C, the maximum resonance frequency in detected electromagnetic impedance and resonance frequency signals of IPA solutions in DI water changes with the concentration of IPA. For IPA solution in DI water, resonance frequency increases as the concentration of IPA increases. Therefore, by identifying the maximum resonance frequency from the resistance-frequency signal of a known solution, it is possible to determine the concentration of the solution using the impurity monitoring apparatus according to the present disclosure.

FIG. 3D is a schematic chart showing using the impurity monitoring apparatus 100 to detect level of usage of a filter. FIG. 3D includes obtained capacitance values for IPA filters at different levels of use. Particularly, for IPA filters, as an IPA filter being consumed, the resonance capacitance increases. The resonance capacitance of a filter may be used to determine the status of the filter. Therefore, a filter replacement alert may be triggered when the obtained capacitance of a filter reaches a pre-set value. Therefore, by determining the resonance capacitance of a filter, it is possible to determine the level of use of a filter using the impurity monitoring apparatus according to the present disclosure.

FIG. 3E is a schematic chart showing using the impurity monitoring apparatus 100 to the presence and concentration of a specific type of particles. FIG. 3E includes obtained impedance-frequency curves of an IPA solutions with different concentrations of gold nano particles. Because gold is conductive, gold nano particles in an IPA solution reduces impedance of the IPA solution. Concentrations of the gold nano particles are detected using obtained impedance values. Similarly, the method may be used to determine other conductive particles in a solution. Therefore, by determining the impedance of a solution, it is possible to determine a concentration of conductive particles in the solution using the impurity monitoring apparatus according to the present disclosure.

FIG. 3F is a schematic chart showing using the impurity monitoring apparatus 100 to detect level of usage of a filter. FIG. 3F includes obtained impedance and capacitance reactance of an ion/chemical filtration filter. As the filter being used, increasing amount of ion/chemical becomes present in the filter. The increased ion/chemical causes the impedance and capacitance reactance to increase. Additionally, the maximum resonance frequency also increases as the number of ion/chemical increases in the filter. Therefore, by determining the resonance impedance and capacitance reactance of a filter, it is possible to determine the level of use of an ion/chemical filtration filter using the impurity monitoring apparatus according to the present disclosure.

FIG. 3G is a schematic chart showing using the impurity monitoring apparatus 100 to detect level of usage of a filter. FIG. 3G includes obtained inductive reactance of a particle filtration filter. As the filter being used, increasing number of particles becomes present in the filter. The increased particles cause the inductive reactance to decrease. Additionally, the maximum resonance frequency also increases as the number of particles increases in the filter. Therefore, by determining the inductance reactance of a filter, it is possible to determine the level of use of a particle filtration filter using the impurity monitoring apparatus according to the present disclosure.

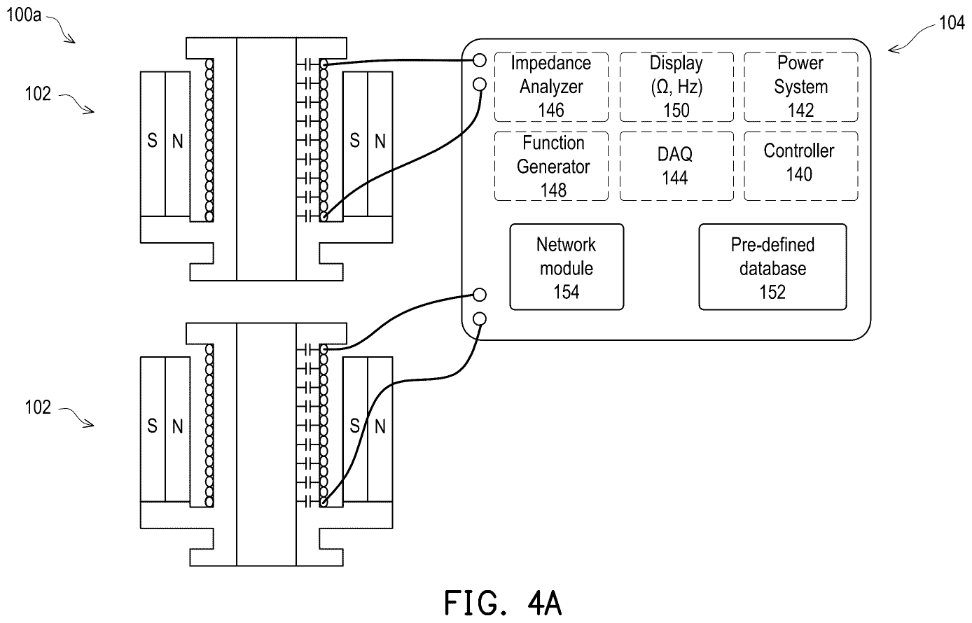

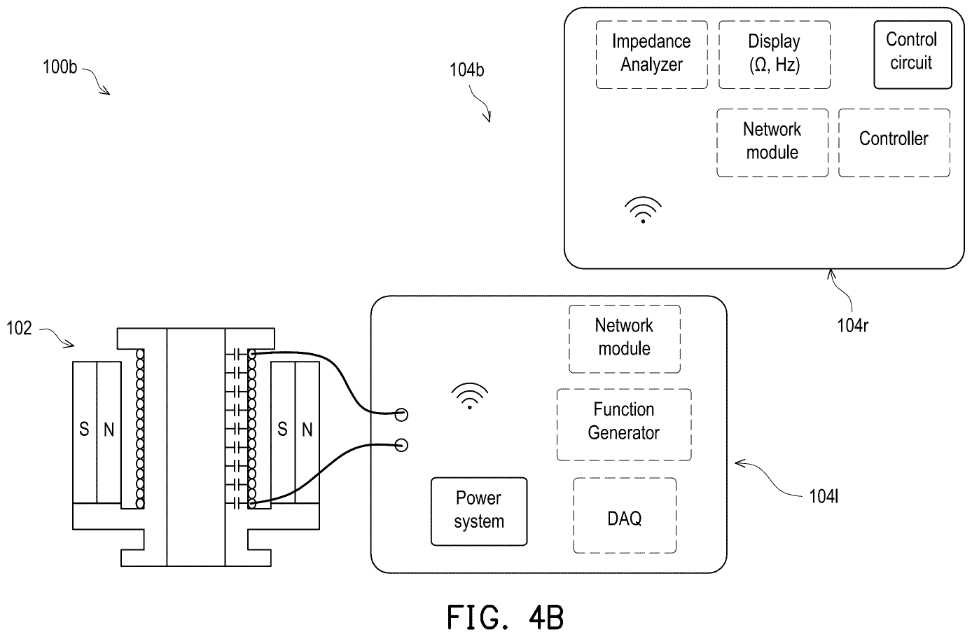

FIGS. 4A-4B schematically illustrate impurity monitoring apparatus according to other embodiments of the present disclosure. FIG. 4A schematically illustrates an impurity monitoring apparatus 100a according to embodiments of the present disclosure. The impurity monitoring apparatus 100a is similar to the impurity monitoring apparatus 100 of FIG. 1A except that the impurity monitoring apparatus 100a includes two or more detection module 102 connected to the analyzing module 104. The impurity monitoring apparatus 100a may be used to monitor two or more locations in a system. FIG. 4B schematically illustrates an impurity monitoring apparatus 100b according to embodiments of the present disclosure. The impurity monitoring apparatus 100b is similar to the impurity monitoring apparatus 100 of FIG. 1A except that the impurity monitoring apparatus 100b includes one or more remote portions. For example, the impurity monitoring apparatus 100b includes an analyzing module 104b having a local portion 1041 and a remote portion 104r. The local portion 1041 is connected to the detection module 102 and may be disposed in cleaning rooms with the process tool to be monitored. The remote portion 104r may be disposed outside the clean rooms and communicate with the local portion 1041 via wired or wireless communication. The impurity monitoring apparatus 100b has a reduced footprint in the cleanroom, therefore, reducing operation cost.

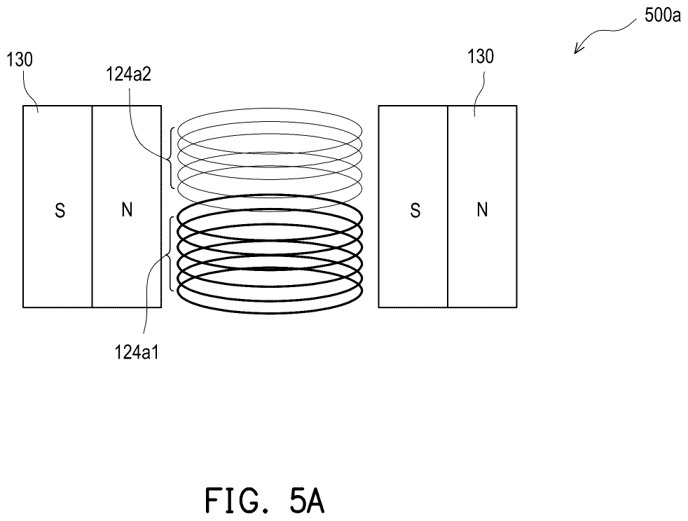

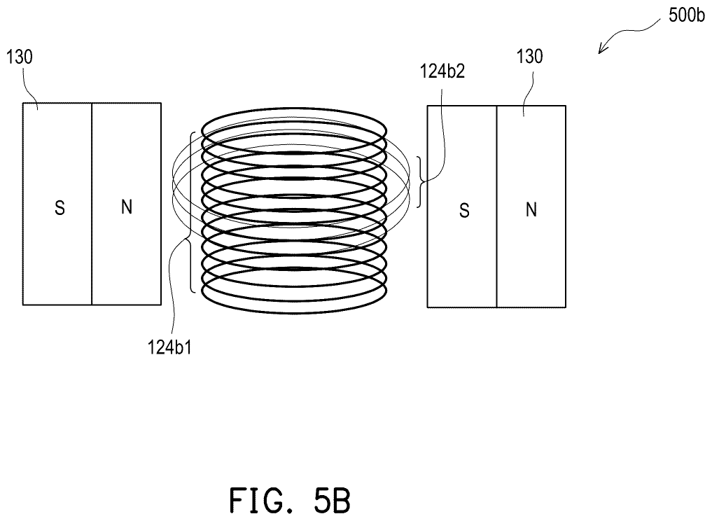

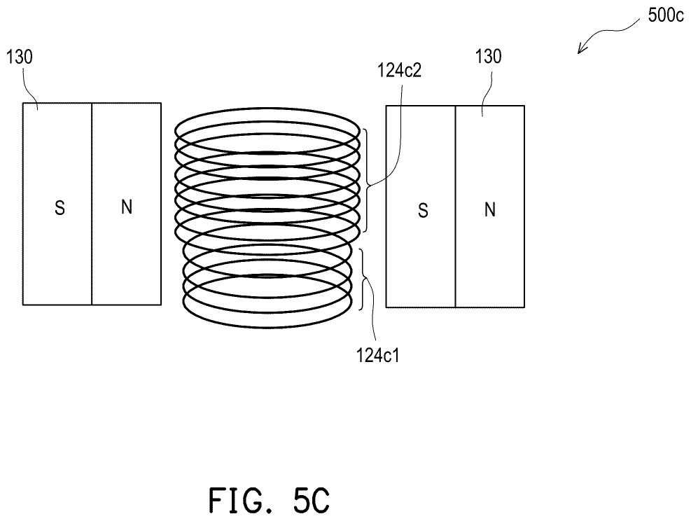

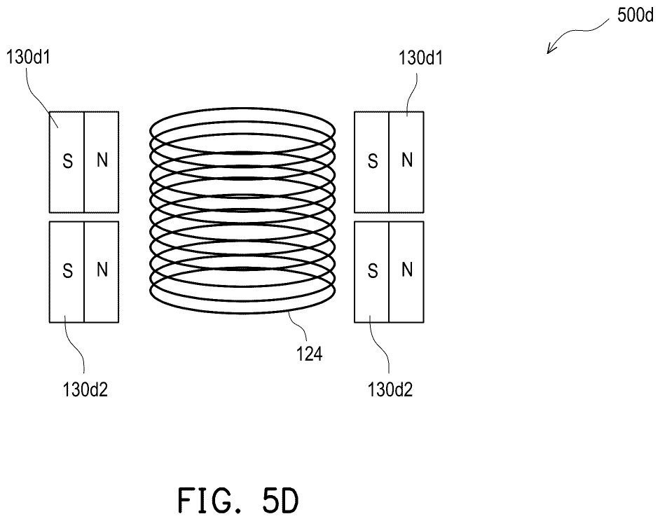

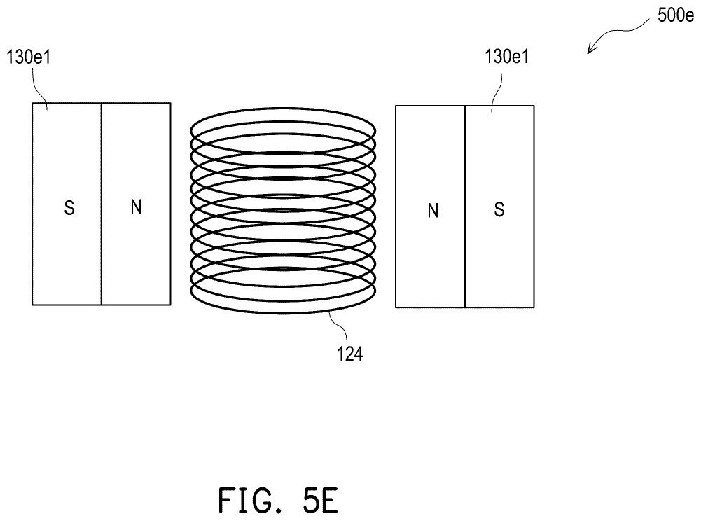

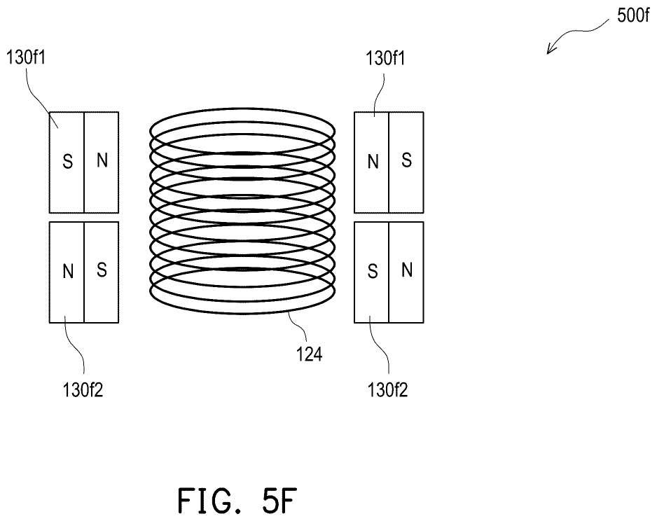

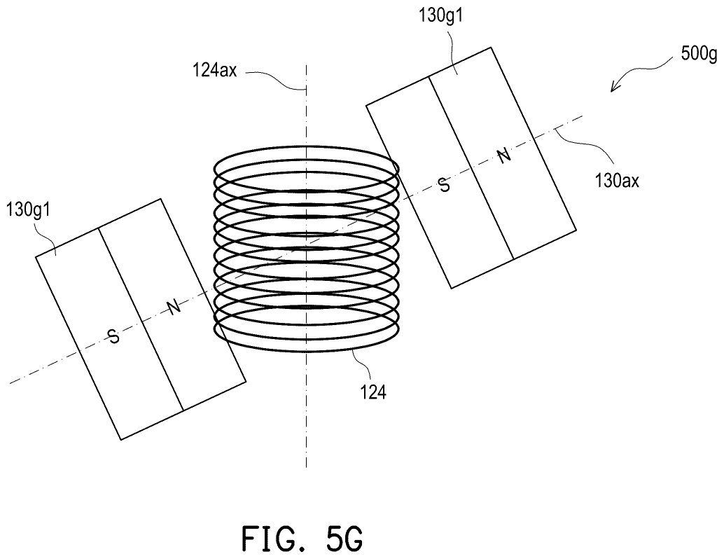

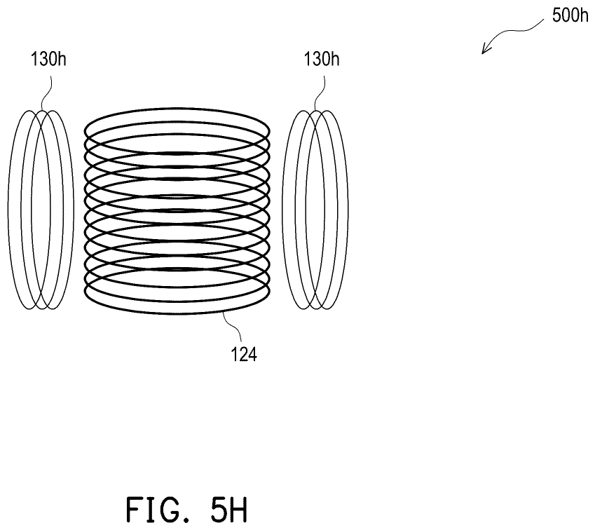

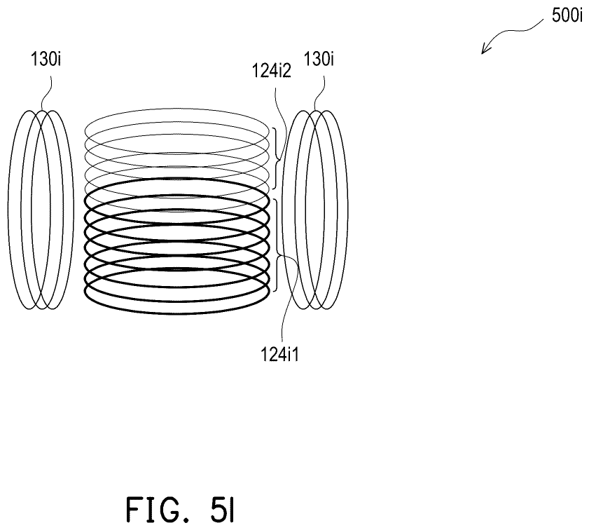

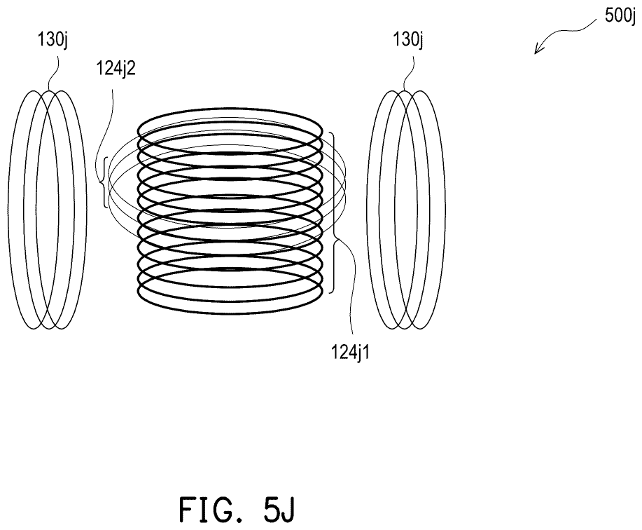

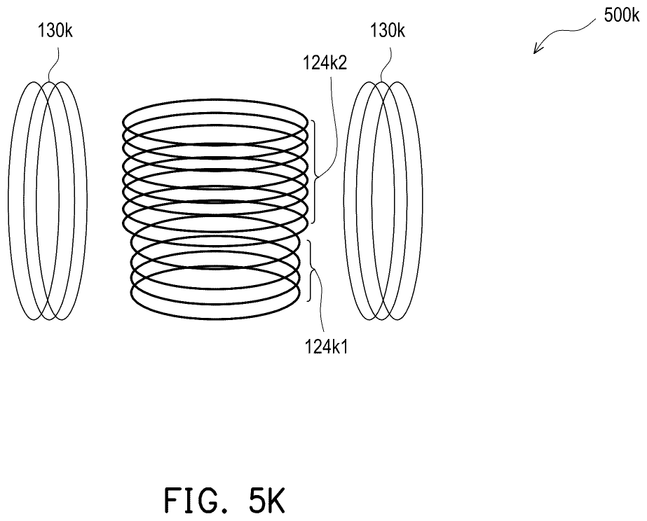

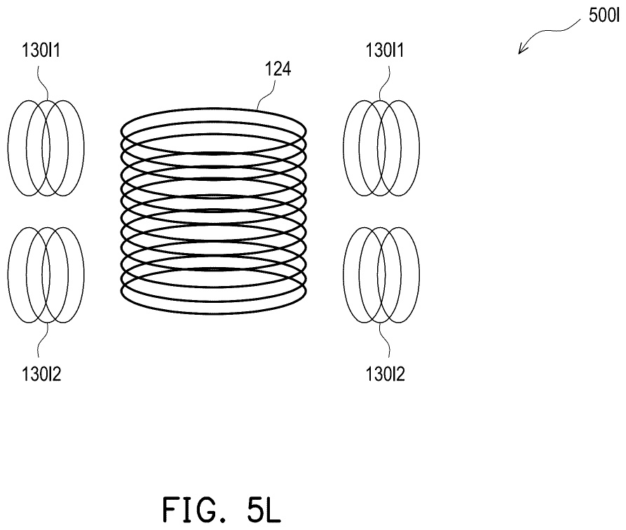

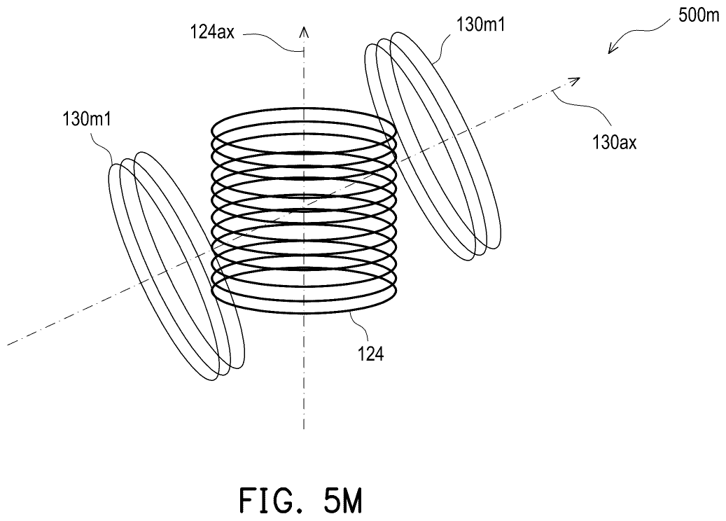

Impurity monitoring apparatus according to embodiments of the present disclosure may include various magnet and coil arrangement to achieve different designs. FIGS. 5A-5G schematically illustrate various magnet and coil arrangements according to embodiments of the present disclosure. The magnet and coil arrangements may be used in place of the magnet assembly 130 and the coil assembly 124 in the impurity monitoring apparatus 100.

FIG. 5A schematically illustrates a magnet and coil arrangement 500a according to embodiments of the present disclosure. The magnet and coil arrangement 500a is similar to the arrangement in the impurity monitoring apparatus 100 described above except that the magnet and coil arrangement 500a includes two coil assemblies 124a1 and 124a2 in place of the single coil assembly 124. The coil assemblies 124a1 and 124a2 may be vertically stacked. Each of the coil assemblies 124a1, 124a2 is similar to the coil assembly 124 and may be used to supply a pulsed RF wave and to sense a reactant impedance after the pulsed RF wave terminates. In some embodiments, the coil assemblies 124a1, 124a2 may supply RF waves of different frequencies to focus on different species of impurities. In some embodiments, the coil assemblies 124a1, 124a2 may have different dimensions, such as different axial lengths, different diameters, and/or different coil densities. Even though two coil assemblies 124a1, 124a2 are shown in FIG. 5A, the magnet and coil arrangement 500a may include additional coil assemblies.

FIG. 5B schematically illustrates a magnet and coil arrangement 500b according to embodiments of the present disclosure. The magnet and coil arrangement 500b is similar to the magnet and coil arrangement 500a of FIG. 5A except that the magnet and coil arrangement 500b includes two coil assemblies 124b1 and 124b2 concentrically arranged.

FIG. 5C schematically illustrates a magnet and coil arrangement 500c according to embodiments of the present disclosure. The magnet and coil arrangement 500c is similar to the magnet and coil arrangement 500a of FIG. 5A except that the magnet and coil arrangement 500b includes two coil assemblies 124c1 and 124c2 having different diameters.

FIG. 5D schematically illustrates a magnet and coil arrangement 500d according to embodiments of the present disclosure. The magnet and coil arrangement 500d is similar to the arrangement in the impurity monitoring apparatus 100 described above except that the magnet and coil arrangement 500d includes two pairs of magnets 130d1, 130d2 in place of the single pair of magnet assembly 130. The two pairs of magnets 130d1, 130d2 may be vertically stacked. Each pair of magnets 130d1, 130d2 is configured to impose a base magnetic field to a portion of the testing volume, which is defined within the coil assembly 124. In some embodiments, the two pairs of magnets 130d1, 130d2 may have different properties, for example, different dimensions, and/or different magnetic strengths. Even though two pairs of magnets 130d1, 130d2 are shown in FIG. 5D, the magnet and coil arrangement 500d may include additional pairs of magnets.

FIG. 5E schematically illustrates a magnet and coil arrangement 500e according to embodiments of the present disclosure. The magnet and coil arrangement 500e is similar to the arrangement in the impurity monitoring apparatus 100 described above except that the magnet and coil arrangement 500e includes a pair of magnets 130e1 arranged in opposite directions. The pair of magnets 130e1 impose a different magnetic field in the testing volume.

FIG. 5F schematically illustrates a magnet and coil arrangement 500f according to embodiments of the present disclosure. The magnet and coil arrangement 500f is similar to the magnet and coil arrangement 500e except that the magnet and coil arrangement 500f includes two pairs of magnets 130f1, 130f2 arranged in opposite directions.

FIG. 5G schematically illustrates a magnet and coil arrangement 500g according to embodiments of the present disclosure. The magnet and coil arrangement 500g is similar to the arrangement in the impurity monitoring apparatus 100 described above except that the magnet and coil arrangement 500g includes a pair of magnets 130g1 arranged along an axis 130ax which is not perpendicular to an axis 124ax of the coil assembly 124. The axis 130ax and 124ax are at an angle. In some embodiments, the axis 130ax and 124ax are at an angle are arranged at an angle between about 10 degrees and 80 degrees.

FIG. 5H schematically illustrates a magnet and coil arrangement 500h according to embodiments of the present disclosure. The magnet and coil arrangement 500h is similar to the arrangement in the impurity monitoring apparatus 100 described above except that the magnet and coil arrangement 500h includes a pair of base coils 130h configured to generate a base magnetic field in the testing volume. By replacing permanent magnets with coils, the magnet and coil arrangement 500h provide flexibility of in terms of strength and distribution of the base magnetic field for testing. In some embodiments, alternative current (AC) power source may be applied to the base coil 130h to generate a base magnetic field. In some embodiments, the distribution of the base magnetic field may be adjusted by tuning the phase of the AC power supplied to the pair of base coils 130h.

FIG. 5I schematically illustrates a magnet and coil arrangement 500i according to embodiments of the present disclosure. The magnet and coil arrangement 500i is similar to the magnetic and coil arrangement 500h in FIG. 5H except that the magnet and coil arrangement 500i includes a pair of main coils 130i and two coil assemblies 124i1 and 12412 in place of the single coil assembly 124. The coil assemblies 124i1 and 124i2 may be vertically stacked.

FIG. 5J schematically illustrates a magnet and coil arrangement 500j according to embodiments of the present disclosure. The magnet and coil arrangement 500j is similar to the magnetic and coil arrangement 500i in FIG. 5I except that the magnet and coil arrangement 500i includes a pair of main coils 130j and two coil assemblies 124j1 and 124j2 concentrically arranged.

FIG. 5K schematically illustrates a magnet and coil arrangement 500k according to embodiments of the present disclosure. The magnet and coil arrangement 500k is similar to the magnetic and coil arrangement 500i in FIG. 5I except that the magnet and coil arrangement 500k includes a pair of main coils 130k and two coil assemblies 124k1 and 124k2 having different diameters.

FIG. 5L schematically illustrates a magnet and coil arrangement 500i according to embodiments of the present disclosure. The magnet and coil arrangement 500i is similar to the magnet and coil arrangement 500h of FIG. 5H except that the magnet and coil arrangement 500i includes two pairs of main coils 13011, 13012 vertically stacked.

FIG. 5M schematically illustrates a magnet and coil arrangement 500m according to embodiments of the present disclosure. The magnet and coil arrangement 500m is similar to the magnet and coil arrangement 500g of FIG. 5G except that the magnet and coil arrangement 500M includes a pair of main coils 130m1 arranged along an axis 130ax which is not perpendicular to an axis 124ax of the coil assembly 124. The axis 130ax and 124ax are at an angle. In some embodiments, the axis 130ax and 124ax are at an angle are arranged at an angle between about 10 degrees and 80 degrees.

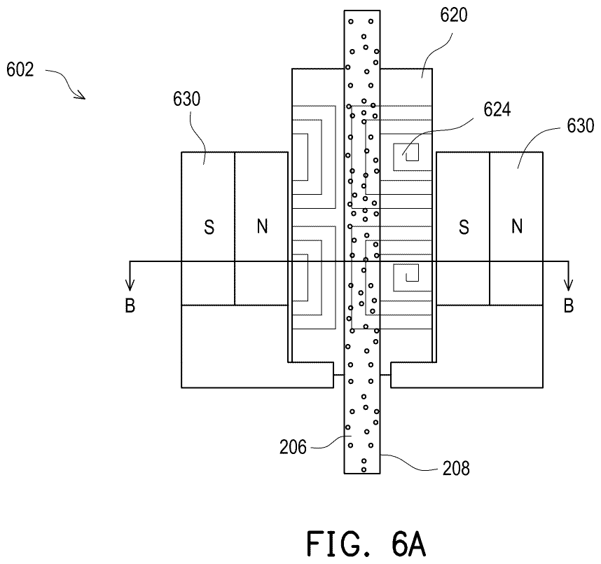

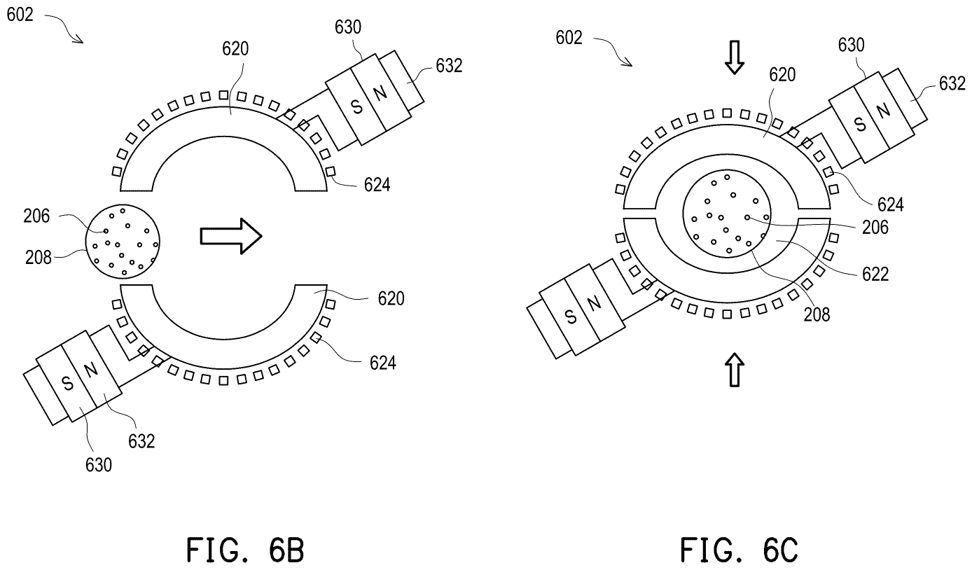

FIGS. 6A-6C schematically illustrate a detection module 602 for using in impurity monitoring apparatus according to embodiments of the present disclosure. The detection module 602 may move between an open position and a close position. FIG. 6A is a schematic perspective view of the detection module 602 in the closed position surrounding a supply tubing 206. FIG. 6B is a cross sectional view of the detection module 602 in the open position. FIG. 6C is a cross sectional view of the detection module 602 in the closed position. The detection module 602 may be used in place of the detection modules 102 described above.

The detection module 602 includes a housing 620 that is movable between the opening position and the closed position. In some embodiments, the housing 620 includes two or more sections. The housing 620 may be selectively opened along an axial direction to allow a testing target to be positioned in a testing volume 622 defined by the housing 620. For example, the detection module 602 may be opened to surround an existing supply tubing without disconnect the supply tubing.

In the embodiments of FIGS. 6A-6C, the housing 620 includes two sections. Each section of the housing 620 includes a semi-circular sidewall, and a flat coil assembly 624 attached to an exterior surface. In some embodiments, each section of the housing 620 incudes a flange section 632. A magnet 630 is disposed on the flange section 632. The flat coil assembly 624 allows sections of the housing 620 to open without affecting the wiring. In some embodiments, the flat coil assembly 624 includes one or more spiral coils wound on a surface, such as the outer wall of a section of the housing 620. The flat coil assembly 624 may be formed in a planar surface or a curved surface.

In some embodiments, the sections of housing 620 may be separated from one another at the open position, as shown in FIG. 6B, to allow the testing target, for example the supply tubing 206, to be inserted. The sections of housing 620 are then pushed together to the closed position to hold the testing target in the testing volume 622, as shown in FIG. 6C. In other embodiments, the sections of housing 620 may be movably connected, for example, by a hinge, to move between the open and closed position.

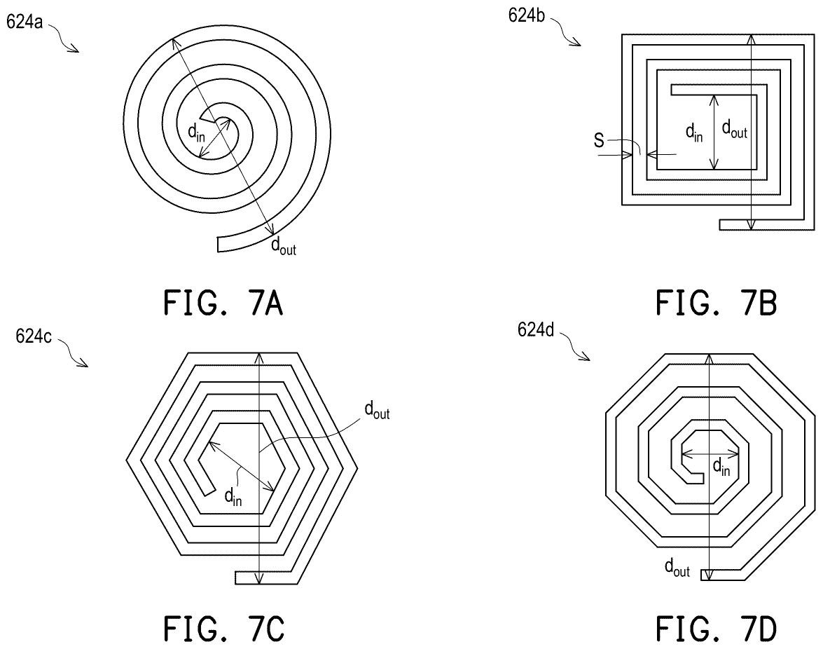

Depending on the surfaces of the housing, the flat coil assembly 624 may have different shapes. FIGS. 7A-7D schematically illustrate several flat coil assemblies according to embodiments of the present disclosure. FIG. 7A illustrates a flat coil assembly 624a in circular shape. FIG. 7B illustrates a flat coil assembly 624b in rectangular shape. FIG. 7C illustrates a flat coil assembly 624c in hexagonal shape. FIG. 7D illustrates a flat coil assembly 624d in octagonal shape.

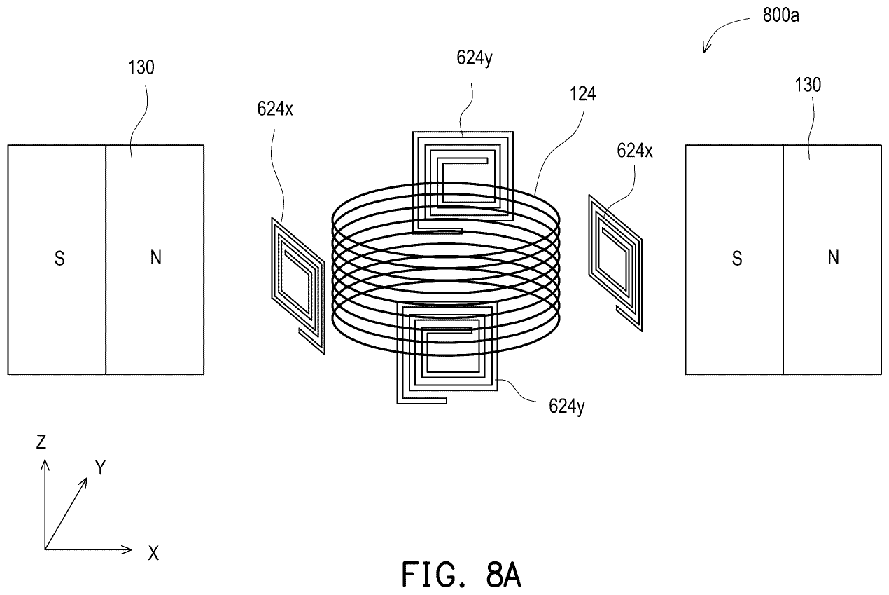

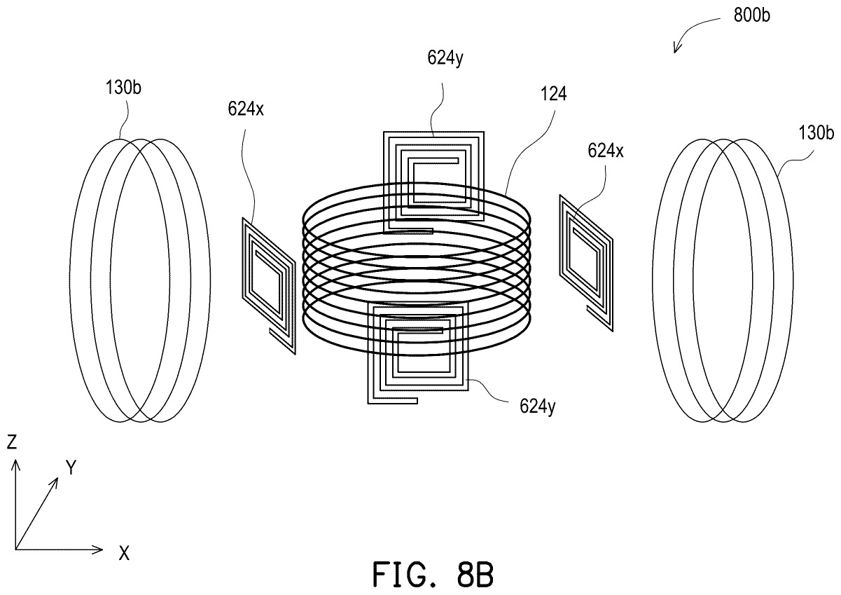

In some embodiments, helical coils and flat coils may be used in combination in the detection module according to embodiments of the present disclosure. FIG. 8A schematically illustrate a magnet and coil arrangement 800a according to embodiments of the present disclosure. The magnet and coil arrangement 800a is similar to the arrangement in the impurity monitoring apparatus 100 described above except that the magnet and coil arrangement 800a includes sets of flat coil assemblies 624x and 624y around the testing volume. In some embodiments, the pair of flat coil assemblies 624x are disposed along the x direction and the pair of flat coil assembly 624y are disposed along the y direction. During operation, the helical coil assembly 124 generate a distributing electromagnetic field along the z direction, the pair of flat coil assemblies 624x generate a distributing electromatic field along the x direction, and the pair of flat coil assembly 624y generates a distributing electromatic field along the y direction. Thus, when supplying pulsed RF waves using the helical coil assembly 124 and the pairs of flat coil assemblies 624x, 624y, it is possible to detect three dimensional impurities distributions.

FIG. 8B schematically illustrates a magnet and coil arrangement 800b according to embodiments of the present disclosure. The magnet and coil arrangement 800b is similar to the magnet and coil arrangement 800a except that the magnet and coil arrangement 800b includes a pair of base coils 130b configured to generate a base magnetic field in the testing volume. By replacing permanent magnets with coils, the magnet and coil arrangement 800b provide flexibility of in terms of strength and distribution of the base magnetic field for testing. In some embodiments, alternative current (AC) power source may be applied to the base coil 130b to generate a base magnetic field. In some embodiments, the distribution of the base magnetic field may be adjusted by tuning the phase of the AC power supplied to the pair of base coils 130b.

Embodiments of the present disclosure relate to apparatus and methods for detecting impurities in semiconductor processing tools in real time. The real time electromagnetic impedance and resonance frequency behavior detection/analysis can provide specific ion/particle/chemical information and/or fingerprint in the semiconductor process. Particularly, the impurity monitoring apparatus according to the present disclosure can provide real time impurity detection to ppb level in real time. The impurity monitoring apparatus according to the present disclosure may prevent filter overuse or underuse. The impurity monitoring apparatus according to present disclosure may provide early alarms with ppb level accuracy.

Some embodiments of the present provide an apparatus, comprising: a detection module comprising: a housing defining a testing volume configured to receive a component of a process tool; a coil assembly disposed on the housing and around the testing volume; and a magnet assembly positioned to impose a magnetic field in the testing volume; an analyzing module electrically connected to the coil assembly, wherein the analyzing module is operable to supply a pulsed radio frequency wave to the coil assembly and detect at least one of inductance, capacitance, and resistance of the detection module.

Some embodiments of the present disclosure provide a system, comprising: a process tool; a process chemical source; a fluid passage connected between the process tool and the process chemical source; and an impurity monitoring apparatus disposed between the process tool and the process chemical source, wherein the impurity monitoring apparatus comprises: a housing disposed around a portion of the fluid passage; a coil assembly disposed on the housing; and a magnet assembly disposed around the portion of the fluid passage.

Some embodiments of the present disclosure provide a method, comprising: supplying a fluid from a process chemical source to a process tool via a fluid passage; applying a base magnetic field to a portion of the fluid passage; applying a pulsed electromagnetic field to the portion of the fluid passage while the base magnetic field is applied on the portion of the fluid passage; after termination of the pulsed electromagnetic field, measuring impedance of the portion of the fluid passage; and determining impurities in the portion of fluid passage from the measured impedance.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. An apparatus, comprising:
a detection module comprising:
a housing defining a testing volume configured to receive a component of a process tool;
a coil assembly disposed on the housing and around the testing volume; and
a magnet assembly positioned to impose a magnetic field in the testing volume;
an analyzing module electrically connected to the coil assembly, wherein the analyzing module is operable to supply a pulsed radio frequency wave to the coil assembly and detect at least one of inductance, capacitance, and resistance of the detection module.

2. The apparatus of claim 1, wherein the housing is configured to receive a filter or a supply tubing of the process tool.

3. The apparatus of claim 1, wherein the coil assembly comprises a helical coil wrapped around the housing.

4. The apparatus of claim 2, wherein the magnet assembly comprises a pair of permanent magnets disposed around the housing.

5. The apparatus of claim 2, wherein the magnet assembly comprises a pair of coils configured to generate an electromagnetic field.

6. The apparatus of claim 1, wherein the housing comprises a first section and a second section movably between an open position and a close position, and the coil assembly comprises a pair of flat coils disposed on the first section and second section of the housing respectively.

7. The apparatus of claim 1, wherein the coil assembly includes a first terminal and a second terminal, and the analyzing module is connected to the first terminal and the second terminal.

8. The apparatus of claim 7, wherein the analyzing module comprises:
a power system;
a function generator;
a data acquisition (DAQ) unit; and
an impedance analyzer.

9. A system, comprising:
a process tool;
a process chemical source;
a fluid passage connected between the process tool and the process chemical source; and
an impurity monitoring apparatus disposed between the process tool and the process chemical source, wherein the impurity monitoring apparatus comprises:
a housing disposed around a portion of the fluid passage;
a coil assembly disposed on the housing; and
a magnet assembly disposed around the portion of the fluid passage.

10. The system of claim 9, wherein the impurity monitoring apparatus further comprises:
a RF power source connected to the coil assembly; and
a data acquisition (DAQ) unit connected to the coil assembly.

11. The system of claim 10, wherein the impurity monitoring apparatus further comprises an impedance analyzer.

12. The system of claim 9, wherein the fluid passage comprises a filter, and the housing is disposed around the filter.

13. The system of claim 9, wherein the fluid passage comprises a supply tubing, and the housing is disposed around the supply tubing.

14. The system of claim 9, wherein the process tool is one of an etch process apparatus, an lithography process apparatus, an chemical mechanical polishing (CMP) process apparatus, a chemical vapor deposition (CVD) process apparatus, a physical vapor deposition (PVD) process apparatus, an atomic layer deposition (ALD) process apparatus, an electrochemical plating (ECP) process apparatus, an ion implantation process apparatus, a thermal treatment apparatus, a diffusion process apparatus, a waste-water process apparatus, and a waste chemical process apparatus.

15. The system of claim 9, wherein the process chemical source is configured to supply one or more of deionized (DI) water, lithography photoresist, lithography developers, lithography solvent, chemical mechanical polishing slurry, acid liquid, acid gas, acid mixture, alkaline liquid, alkaline mixture, polymer fluid, organic compound fluid, processing gases, and plasma containing gases.

16. A method, comprising:
supplying a fluid from a process chemical source to a process tool via a fluid passage;
applying a base magnetic field to a portion of the fluid passage;
applying a pulsed electromagnetic field to the portion of the fluid passage while the base magnetic field is applied on the portion of the fluid passage;
after termination of the pulsed electromagnetic field, measuring impedance of the portion of the fluid passage; and
determining impurities in the portion of fluid passage from the measured impedance.

17. The method of claim 16, wherein applying the pulsed electromagnetic field comprises applying a pulsed radio frequency wave to a coil assembly disposed adjacent the portion of the fluid passage.

18. The method of claim 17, wherein the coil assembly includes a helical coil disposed around the portion of the fluid passage.

19. The method of claim 17, wherein the coil assembly includes a pair of flat coils disposed on opposing sides of the portion of the fluid passage.

20. The method of claim 16, wherein applying the base magnetic field comprises disposing a pair of permanent magnets adjacent the portion of the fluid passage.
